(19) United States
(12) Patent Application Publication
(10) Pub. No.: US 2009/0045391 A1
(43) Pub. Date: Feb. 19, 2009

(54) Switch Device and Method of Fabricating the Same

(75) Inventor: Seok-Jun Won, Seoul (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/132,749

(22) Filed: Jun. 4, 2008

(30) Foreign Application Priority Data
Jun. 27, 2007 (KR) 10-2007-0063803

(51) Int. Cl. H01L 21/283; H01L 29/423

(52) U.S. Cl. 257/9; 438/585; 257/E29.135; 257/E21.159

(57) ABSTRACT

Provided is a switch device that can be reliably turned on or off using a nanostructure that includes a nanotube and/or a nanowire. The switch device includes a lower conductive film formed on a substrate, a first insulating film formed on the lower conductive film and having a first hole that exposes at least a portion of the first lower conductive film, and a conductive film spacer formed on an inner wall of the first hole of the first insulating film. A switch device may include a nanostructure having an end electrically connected to the lower conductive film, including a nanotube and/or a nanowire, extending substantially vertically from the lower conductive film and penetrating through the first hole, and separated from the conductive film spacer with a working gap interposed therebetween.

### CROSS REFERENCE TO RELATED APPLICATIONS

This application claims priority from Korean Patent Application No. 10-2007-0063803 filed on Jun. 27, 2007 in the Korean Intellectual Property Office, the entire contents of which are hereby incorporated by reference.

### BACKGROUND OF THE INVENTION

The present invention relates to a switch device, and more particularly, to a switch device including a nanostructure, a method of fabricating the switch device, a semiconductor memory device including the switch device, and a method of fabricating the semiconductor memory device.

As micro-electronic devices become more highly integrated, their design rules may be rapidly reduced and their processing speed may be increased. Accordingly, line widths of wirings used for micro-electronic devices may be reduced and current density may be increased. Consequently, improved wiring materials may be required. Materials that may be receiving attention in this regard include nanostructures such as a nanotube and/or a nanowire.

Nanostructures may exhibit superior conductivity, which may be controlled according to fabrication methods. In this regard, it may be desirable to replace conductors and/or semiconductors with nanostructures.

### SUMMARY OF THE INVENTION

Some embodiments of the present invention provides a switch device that can be reliably turned on or off using a nanostructure that includes a nanotube and/or a nanowire. Some embodiments of switch devices disclosed herein include a lower conductive film formed on a substrate, a first insulating film formed on the lower conductive film and including a first hole which exposes at least a portion of the lower conductive film, a conductive film spacer formed on an inner wall of the first hole of the first insulating film, and a nanostructure having an end electrically connected to the lower conductive film, the nanostructure including a nanotube and/or a nanowire, extending substantially vertically from the lower conductive film and penetrating through the first hole, and separated from the conductive film spacer with a working gap interposed therebetween.

Some embodiments include a supporting film disposed under the first insulating film and having a second hole that exposes the at least a portion of the lower conductive film together with the first hole, wherein the nanostructure penetrates through the second hole and the first hole and extends substantially vertically. Some embodiments include an upper conductive film that is configured to contact the conductive film spacer and to include a sidewall aligned with the inner wall of the first hole or an inner sidewall of the conductive film spacer. In some embodiments, the upper conductive film is formed on the first insulating film and/or between the first insulating film and the supporting film. In some embodiments, the first insulating film includes a first lower insulating film and a first upper insulating film that are sequentially stacked and provide that the upper conductive film is formed between the first lower insulating film and the first upper insulating film.

In some embodiments, an inner diameter of space defined by the inner sidewall of the conductive film spacer is greater than an inner diameter of the second hole and wherein the supporting film protrudes from the inner sidewall of the conductive film spacer. In some embodiments, the working gap includes a spacer-shaped air gap.

Some embodiments include a catalyst layer formed on the lower conductive film, wherein one end of the nanostructure is fixed to the catalyst layer and electrically connected to the lower conductive film by the catalyst layer. Some embodiments include a second insulating film formed on the first insulating film, wherein the second insulating film is configured to cover the first hole and/or support the other end of the nanostructure. In some embodiments, the second insulating film includes a plasma chemical vapor deposition (CVD) silicon oxide film.

Some embodiments include a second insulating film formed on the first insulating Film, wherein the second insulating film includes a line pattern that is configured to expose at least a portion of the nanostructure and at least a portion of the working gap.

Some embodiments of the present invention include a switch device that includes a first conductive film and a nanostructure that includes a nanotube and/or a nanowire on the first conductive film, such that the nanostructure is configured to extend substantially perpendicular to a surface of the first conductive film. Some embodiments include a second conductive film configured to extend substantially parallel to the nanostructure and substantially perpendicular to the surface of the first conductive film, the second conductive film separated from the nanostructure and defining a working gap interposed therebetween.

In some embodiments, the nanostructure is configured to electrically connect or disconnect the first conductive film and the second conductive film responsive to an electro-dynamic force acting on the nanostructure.

Some embodiments of the present invention include methods of fabricating a switch device. Such methods may include forming a lower conductive film on a substrate, forming a first insulating film on the lower conductive film, patterning the first insulating film to form a first hole in the first insulating film, and forming a conductive film spacer on an inner wall of the first hole. Methods may include forming a sacrificial spacer on a sidewall of the conductive film spacer, forming a nanostructure including one end electrically connected to the lower conductive film, the nanostructure comprising a nanotube and/or a nanowire, the nanostructure extending substantially vertically from the lower conductive film and penetrating through the first hole, and removing the sacrificial spacer to define a working gap interposed between the nanostructure and the conductive film spacer.

Some embodiments include forming a supporting film on the lower conductive film before forming the first insulating film and forming a second hole, which exposes the lower conductive film, in the supporting film by etching the supporting film using the sacrificial spacer as an etch mask after forming the sacrificial spacer, wherein the nanostructure is formed to penetrate through the second hole and the first hole and extend substantially vertically.

Some embodiments include forming a film for at least one upper conductive film before forming the first insulating film and forming an upper conductive film that includes a sidewall aligned with an inner sidewall of the sacrificial spacer by patterning the film for the at least one upper conductive film after forming the sacrificial spacer. Some embodiments include forming a film for at least one upper conductive film after forming the first insulating film and forming an upper conductive film that includes a sidewall aligned with the inner wall of the first hole by patterning the film for the at least one upper conductive film after forming the first hole.

In some embodiments, forming the first insulating film includes forming a first lower insulating film and forming a first upper insulating film. In some embodiments, forming the first insulating film includes forming the first lower insulating film on the supporting film, forming a film for at least one upper conductive film on the first lower insulating film, and forming the first upper insulating film on the film for at least one upper conductive film. In some embodiments, patterning the first insulating film includes patterning the first upper insulating film, the film for at least one upper conductive film and the first lower insulating film, wherein patterning the upper conductive films includes forming an upper conductive film that has a sidewall aligned with the inner wall of the first hole.

Some embodiments include forming a catalyst layer on the lower conductive film. In some embodiments, forming the nanostructure includes vertically growing the nanostructure on the catalyst layer. In some embodiments, removing the sacrificial spacer includes performing a wet-etching process. Some embodiments include forming a second insulating film on the first insulating film after removing the sacrificial spacer, the second insulating film configured to cover the first hole and/or support the other end of the nanostructure. In some embodiments, forming the second insulating film includes forming a plasma CVD silicon oxide film.

Some embodiments include forming a second insulating film on the first insulating film before removing the sacrificial spacer. In some embodiments, the second insulating film includes a line pattern exposing at least a portion of the nanostructure and at least a portion of the working gap.

Some embodiments of the present invention include a semiconductor memory device that includes a cell transistor on a semiconductor substrate, a bitline electrically connected to a first source/drain region of the cell transistor via a bitline contact, and a storage contact electrically connected to a second source/drain region of the cell transistor. The device may include a supporting film formed on the storage contact and including a second hole that exposes at least a portion of the storage contact, a first insulating film formed on the supporting film and including a first hole that exposes the second hole, a conductive film spacer formed on an inner wall of the first hole of the first insulating film and a nanostructure including a first end electrically connected to the storage contact, the nanostructure extending substantially vertically from the storage contact, penetrating through the first hole and separated from the conductive film spacer to define a working gap interposed therebetween, the nanostructure comprising a nanotube and/or a nanowire.

Some embodiments include an upper conductive film contacting the conductive film spacer and including a sidewall aligned with the inner wall of the first hole and/or an inner sidewall of the conductive film spacer. In some embodiments, an inner diameter of a volume defined by the inner sidewall of the conductive film spacer is greater than an inner diameter of the second hole and wherein the supporting film protrudes from the inner sidewall of the conductive film spacer. In some embodiments, the working gap includes a spacer-shaped air gap.

Some embodiments of the present invention include methods of fabricating a semiconductor memory device. Embodiments of such methods may include forming a cell transistor on a semiconductor substrate, forming a bitline that is electrically connected to a first source/drain region of the cell transistor via a bitline contact, forming a storage contact that is electrically connected to a second source/drain region of the cell transistor, and forming a supporting film formed on the storage contact. Methods may include forming a first insulating film formed on the supporting film, forming a first hole in the first insulating film by patterning the first insulating film, forming a conductive film spacer on an inner wall of the first hole, and forming a sacrificial spacer on a sidewall of the conductive film spacer. Methods may include forming a second hole in the supporting film by etching the supporting film using the sacrificial spacer as an etch mask, the second hole exposing the storage contact, forming a nanostructure that includes a first end electrically connected to the storage contact, extends substantially vertically from the storage contact, penetrates through the second hole and the first hole, and is separated from the conductive film spacer, and removing the sacrificial spacer to define a working gap interposed between the nanostructure and the conductive film spacer. In some embodiments, the nanostructure includes a nanotube and/or a nanowire. In some embodiments, removing of the sacrificial spacer includes performing a wet-etching process.

### BRIEF DESCRIPTION OF THE DRAWINGS

FIG. 1 is a schematic circuit diagram illustrating a switch device according to some embodiments of the present invention.

FIG. 2A is a cross-sectional view of a switch device when turned off according to some embodiments of the present invention.

FIG. 2B is a schematic layout of the switch device illustrated in FIG. 2A.

FIG. 3A is a cross-sectional view of a switch device when turned on according to some embodiments of the present invention.

FIG. 3B is a schematic layout of the switch device illustrated in FIG. 3A.

FIGS. 4 through 9A are cross-sectional views of a switch device according to some embodiments of the present invention.

FIG. 9B is a schematic layout of the switch device illustrated in FIG. 9A.

FIGS. 10 through 19 are cross-sectional views sequentially illustrating processing processes included in operations for fabricating a switch device according to some embodiments of the present invention.

FIGS. 20 through 26A are cross-sectional views sequentially illustrating processing processes included in operations for fabricating a switch device according to some embodiments of the present invention.

FIG. 26B is a schematic layout of the switch device illustrated in FIG. 26A.

FIG. 27A is a cross-sectional view of a semiconductor memory device according to some embodiments of the present invention.

FIG. 27B is a schematic circuit diagram for explaining the operation of the semiconductor memory device illustrated in FIG. 27A.

### DETAILED DESCRIPTION OF THE INVENTION

The present invention will now be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art.

It will be understood that, although the teens first, second, etc. may be used herein to describe various elements, these elements should not be limited by these terms. These teens are only used to distinguish one element from another element. Thus, a first element discussed below could be termed a second element without departing from the scope of the present invention. In addition, as used herein, the singular forms “a”, “an” and “the” are intended to include the plural forms as well, unless the context clearly indicates otherwise. It also will be understood that, as used herein, the term “comprising” or “comprises” is open-ended, and includes one or more stated elements, steps and/or functions without precluding one or more unstated elements, steps and/or functions. The term “and/or” includes any and all combinations of one or more of the associated listed items.

It will also be understood that when an element is referred to as being “connected” to another element, it can be directly connected to the other element or intervening elements may be present. In contrast, when an element is referred to as being “directly connected” to another element, there are no intervening elements present. It will also be understood that the sizes and relative orientations of the illustrated elements are not shown to scale, and in some instances they have been exaggerated for purposes of explanation. Like numbers refer to like elements throughout.

In the figures, the dimensions of structural components, including layers and regions among others, are not to scale and may be exaggerated to provide clarity of the concepts herein. It will also be understood that when a layer (or layer) is referred to as being ‘on’ another layer or substrate, it can be directly on the other layer or substrate, or can be separated by intervening layers. Further, it will be understood that when a layer is referred to as being ‘under’ another layer, it can be directly under, and one or more intervening layers may also be present. In addition, it will also be understood that when a layer is referred to as being ‘between’ two layers, it can be the only layer between the two layers, or one or more intervening layers may also be present.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

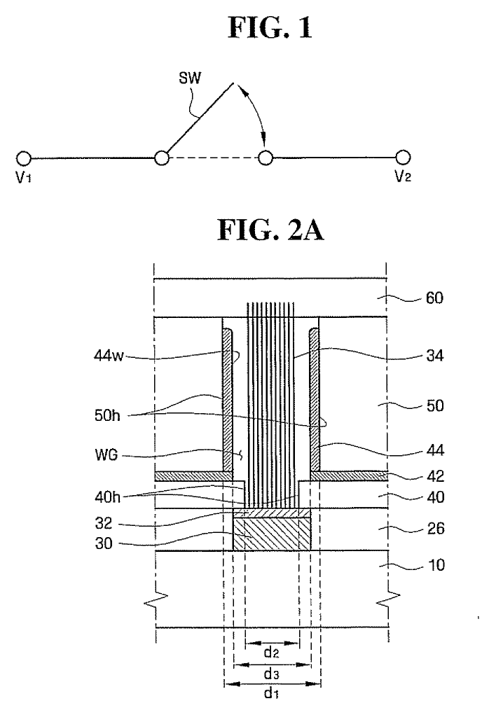

FIG. 1 is a schematic circuit diagram of a switch device according to an exemplary embodiment of the present invention. Referring to FIG. 1, the switch device according to the some embodiments includes a first node, a second node, and a switch SW electrically switching on or off the first and second nodes. A first voltage V₁ is applied to the first node, and a second voltage V₂ is applied to the second node. The switch SW is turned on or off by the difference between the first voltage V₁ and the second voltage V₂ or polarities of the first voltage V₁ and the second voltage V₂. For example, if the first voltage V₁ and the second voltage V₂ have different polarities, the switch SW is turned off. If the first voltage V₁ and the second voltage V₂ have substantially identical polarities, the switch SW is turned on.

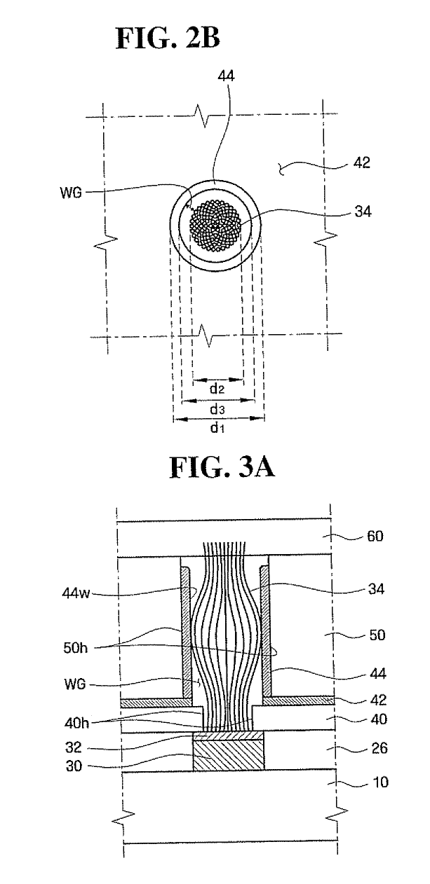

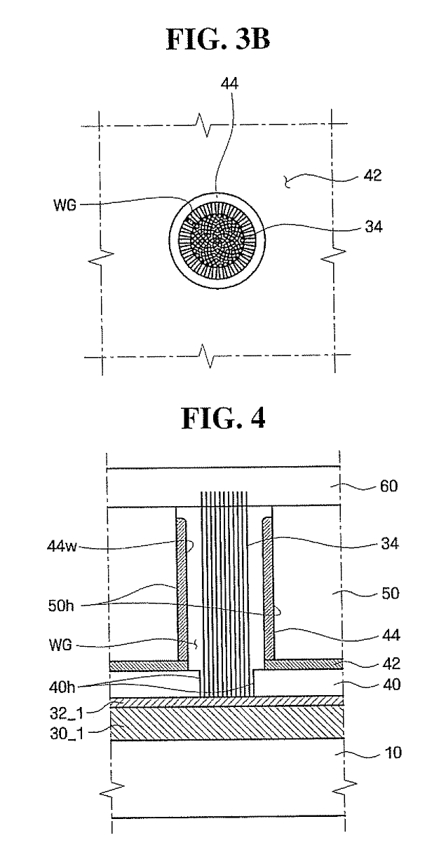

A switch device implementing the above operation according to some embodiments of the present invention is illustrated in FIGS. 2A through 3B. FIGS. 2A and 3A are cross-sectional views of a switch device according to some embodiments of the present invention. Specifically, FIG. 2A illustrates the switch device when turned off, and FIG. 3A illustrates the switch device when turned on. FIGS. 2B and 3B are layouts of the switch device when turned on and when turned off, respectively.

Referring to FIGS. 2A and 2B, the switch device according to the some embodiments includes a lower conductive film 30 on a substrate 10, a first insulating film 50 having a first hole 50h, which exposes the lower conductive film 30, a conductive film spacer 44 formed on an inner wall of the first hole 50h, and a nanostructure 34 extending vertically from the lower conductive film 30.

In some embodiments, the substrate 10 may be a semiconductor substrate, which is made of Si, SiGe, SiGe, GaP, GaAs, SiC, SiGeC, InAs, InP or a compound formed of a selective combination of the same, a silicon on insulator (SOI) substrate, a plastic substrate, and/or a glass substrate.

Some embodiments provide that an insulating film 26 is formed on the substrate 10, and the lower conductive film 30 is buried within the insulating film 26. In some embodiments, the lower conductive film 30 is a first node of the switch device and may be an electrode, a signal line, a connection wiring, a contact and/or a contact plug, among others. Some embodiments provide that the lower conductive film 30 may be a single layer of one or more metals selected from, for example, W, Ti, TiN, TaN, Al and/or Cu, or a stacked layer of the same.

In some embodiments, a catalyst layer 32 is formed on the lower conductive film 30. The catalyst layer 32 may have the substantially same pattern as the lower conductive film 30 and may be buried within the insulating film 26, together with the lower conductive film 30. Some embodiments provide that the catalyst layer 32 may include one or more metal layers selected from the croup consisting of Ni, Fe, Co, Pd, In and/or W and/or a metal silicide layer selected from the group consisting of Ni, Fe, Co, Pd, In, and/or W. In some embodiments, the metal layers and/or the metal silicide layer may further include P and B. In some embodiments, the catalyst layer 32 may be a stack of a low-resistance metal layer and/or a transition metal layer. Some embodiments provide that the low-resistance metal layer may include one or more of W, Ti, Ta, Cu, Al, TiN and TaN, and the transition metal layer may include one or more of Ni, Fe and Co.

In some embodiments, the first insulating film 50 is disposed on the lower insulating film 30. Some embodiments provide that the first insulating film 50 may be formed of a silicon oxide film or a silicon nitride film. The first insulating film 50 may include the first hole 50h, which exposes the lower conductive film 30 and through which the nanostructure 34 to be described later penetrates.

In some embodiments, the conductive film spacer 44 is disposed on the inner wall of the first hole 50h. The conductive film spacer 44 may be spacer-shaped and extend substantially vertically along the inner wall of the first hole 50h. In some embodiments, the conductive film spacer 44 is a second node of the switch device and may be formed of a metal nitride film such as TiN, Tan and/or Wn, among others. In some embodiments, the conductive film spacer 44 may be formed of various other conductive materials.

In some embodiments of the present invention, a supporting film 40 may be formed on the lower conductive film 30 under the first insulating film 50. Some embodiments provide that the supporting film 40 includes a second hole 40h exposing the lower conductive film 30. An inner wall of the second hole 40h formed of the supporting film 40 may support a substantially vertical disposition of the nanostructure 34. In some embodiments, the supporting film 40 may function as an etch-stop film which may prevent the catalyst layer 32 from being exposed when the first hole 50h is etched. The supporting film 40 may be Conned of a silicon nitride film and/or a silicon oxy-nitride film, among others.

Like the first hole 50, the second hole 40h may provide space through which the nanostructure 34 can penetrate and in which the nanostructure 34 may be disposed substantially vertically. In some embodiments, the first hole 50h may frilly expose the second hole 40h. In this regard, a first inner diameter d₁ of the first hole 50h may be greater than a second inner diameter d₂ of the second hole 40h. In some embodiments, in order to provide a working gap WG which will be described later, a third inner diameter d₃ of a third hole defined by an inner sidewall 44w of the conductive film spacer 44, which is Conned on the inner wall of the first hole 50h, may be greater than the second inner diameter d₂ of the second hole 40h. Some embodiments provide that the supporting film 40 may protrude from the inner sidewall 44w of the conductive film spacer 44 toward the center of the first hole 50h and/or the second hole 40h.

Some embodiments provide that the nanostructure 34 penetrates through the second hole 40h and the first hole 50h from the lower conductive film 30 and extends substantially perpendicular to a surface of the substrate 10 and/or the lower conductive film 30. In some embodiments, a lower portion of the nanostructure 34 may be supported by the inner wall of the second hole 40h, which is formed of the supporting film 40. In this manner, the space in which the nanostructure 34 is disposed may be limited to the space that overlaps the second hole 40h. Accordingly, a reliable non-contact (a switchoff) between the nanostructure 34 and the conductive film spacer 44 may be achieved.

As described above, since the third inner diameter d₃ of the third hole defined by the inner sidewall 44w of the conductive film spacer 44 may be greater than second inner diameter d₂ of the second hole 40h, the conductive film spacer 44 and the nanostructure 34 may be separated from each other in proportion to the difference between the third inner diameter d₃ of the third hole and the second inner diameter d₂ of the second hole 40h. If the third hole and the second hole 40G are concentric circles, the distance by which the conductive film spacer 44 and the nanostructure 34 are separated from each other may be half the difference between the third inner diameter d₃ of the third hole and the second inner diameter d₂ of the second hole 40h. Some embodiments provide that the space by which the conductive film spacer 44 and the nanostructure 34 are separated from each other may be provided as the working gap WG. That is, when the switch device is turned off, the nanostructure 34 and the conductive film spacer 44 may be separated from each other by the working gap WG.

The working gap WG may be formed after, for example, a sacrificial spacer is removed, which will also be described later in relation to methods of fabricating a switch device. In this regard, the working gap WG may substantially be a spacer-shaped air gap.

In some embodiments, the nanostructure 34 extends a long distance in a substantially linear shape. The nanostructure 34 may include at least one nanotube or/and at least one nanowire. Some embodiments provide that the nanostructure 34 may include a carbon nanotube and/or a carbon fiber. A single walled carbon nanotube or a multi-walled carbon nanotube with two or more overlapping walls may be applied as the carbon nanotube.

A first end of the nanostructure 34 may be electrically connected to the lower conductive film 30. Some embodiments provide that since the first end of the nanostructure 34 is fixed to the catalyst layer 32 on the lower conductive film 30, it can be electrically connected to the lower conductive film 30. In some embodiments, the other end of the nanostructure 34 may extend to a level equal to or higher than a top surface of the first insulating film 50.

In some embodiments of the present invention, the switch device may include a second insulating film 60 on the first insulating film 50. In this regard, the other end of the nanostructure 34 may be fixed into the second insulating film 60.

In some embodiments, the second insulating film 60 completely covers the first hole 50h. The working cap WG, which will be described later, may be formed in the first hole 50h. Some embodiments provide that the second insulating film 60 may be formed of a material having poor step coverage in order to minimize the permeation of components of the second insulating film 60 into the working gap WG during fabrication. In some embodiments, the second insulating film 60 may be formed of a chemical vapor deposition (CVD) silicon oxide film such as a tetraethoxysilane (P-TEOS) film, among others. Although not shown, some embodiments provide that the second insulating film 60 may partially penetrate into the first hole 50h. Accordingly, some embodiments provide that it may be desirable to form the second insulating film 60 only at an entrance of the first hole 50h, that is, in an upper portion of the first hole 50h, in order to secure a sufficient working gap.

In some embodiments, the switch device may include an upper conductive film 42 contacting the conductive film spacer 44. As illustrated in FIG. 2A, the upper conductive film 42 may be interposed between the first insulating film 50 and the supporting film 40. As illustrated in FIG. 2A, a sidewall of the upper conductive film 42 may be substantially aligned with the inner sidewall 44w of the conductive film spacer 44 and the upper conductive film 42 may contact a lower end of the conductive film spacer 44.

In some embodiments, the sidewall of the upper conductive film 42 may be aligned with the inner wall of the first hole 50. In this regard, the upper conductive film 42 may be formed as a substantially identical pattern to the first insulating film 50. Some embodiments provide that the conductive film spacer 44 extends onto the supporting film 40 on which the upper conductive film 42 is formed. In some embodiments, the upper conductive film 42 contacts an outer sidewall of the conductive film spacer 44.

Some embodiments provide that the upper conductive film 42 functions as an electrode or a power supply line supplying a second voltage to the conductive spacer 44. Accordingly, like the conductive film spacer 44, the upper conductive film 42 may be formed of a metal nitride film such as TiN, Tan and/or Wn, among others. Some embodiments provide that the upper conductive film 42 and the conductive film spacer 44 may be formed of substantially identical materials. However, the present invention is not limited thereto.

As described above, in an initial state in which no voltage has been applied to the lower conductive film 30 and the conductive film spacer 44 (or the upper conductive film 42 connected to the conductive film spacer 44), the switch device is turned off. That is, since the nanostructure 34 is disposed substantially vertically in the initial state, it is separated from the conductive film spacer 44 by the working gap WG. Accordingly, the nanostructure 34 and the conductive film spacer 44 are electrically insulated from each other.

Meanwhile, if voltages of different polarities are applied respectively to the lower conductive film 30 and the conductive film spacer 44 (or the upper conductive film 42 connected to the conductive film spacer 44), electric attraction may occur between them as illustrated in FIGS. 3A and 3B. Accordingly, an electro-dynamic force caused by electric attraction bends the nanostructure 34 and the nanostructure 34 contacts the conductive film spacer 44. In this regard, the lower conductive film 30 may be electrically connected to the conductive film spacer 44, i.e., it is a switch-on state. Some embodiments provide that this switch-on state may be maintained even if voltage supply to the lower conductive film 30 and the conductive film spacer 44 is stopped.

Again, if voltages of the same polarity are applied to the lower conductive film 30 and the conductive film spacer 44, the nanostructure 34 may return to its original state due to a repulsive electrostatic force acting thereon and the nanostructure 34 may be separated from the conductive film spacer 44. That is, as the nanostructure 34 returns to its original state in which it is disposed substantially vertically, the nanostructure 34 and the conductive film spacer 44 are again separated from each other by the working gap WG therebetween as illustrated in FIGS. 2A and 2B. In this regard, the nanostructure 34 may be electrically disconnected from the conductive film spacer 44, i.e., it is a switch-off state. The switch-off state may be maintained even if the voltage supply to the lower conductive film 30 and the conductive film spacer 44 is stopped.

Therefore, it may be understood that the electro-dynamic force of the nanostructure 34 may turn on or off an electrical switch between the nanostructure 34 and the conductive film spacer 44. Since the conductive film spacer 44 extends substantially vertically and parallel to the nanostructure 34, they can contact each other regardless of a position at which the nanostructure 34 bends. In some embodiments, since an area where the conductive film spacer 44 contacts the nanostructure 34 is increased, contact resistance can be reduced. In this regard, the switch device can be reliably turned on or off even if a relatively low voltage is applied thereto.

FIGS. 4 through 9B illustrate a switch device according to some embodiments of the present invention. A description of elements substantially identical to those of previous embodiments described above will be omitted or simplified. Accordingly, the foregoing description will focus on differences relative to previously described embodiments.

The embodiments of FIG. 4 is different from previous embodiments in that a lower conductive film 30_1 is not patterned and may be formed on a whole surface of a substrate 10. In some embodiments, a catalyst layer 32_1 may be formed on the whole surface of the substrate 10, together with the lower conductive film 30_1. Some embodiments provide that in some embodiments, the insulating film 26 burying the lower conductive film 30 and the catalyst layer 32 in FIG. 2A may be omitted.

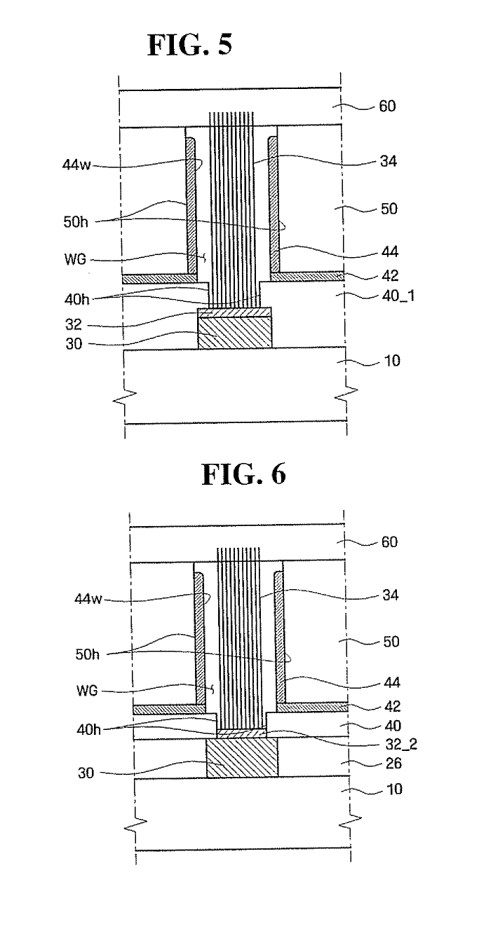

The embodiments of FIG. 5 is different from previous embodiments of FIG. 2A in that an insulating film 40_1 may cover a substrate 10 and a lower conductive film 30 and a catalyst layer 32 may be formed on the substrate 10. In this manner, some embodiments provide that the insulating film 26 and the supporting film 40 illustrated in FIG. 2A is integrated into the insulating film 40_1.

The embodiments of FIG. 6 are different from previous embodiments in that a catalyst layer 32_2 may be formed in a second hole 40h and may have a different pattern from a lower conductive film 30. In some embodiments, the catalyst layer 32_2 may be used to affix a nanostructure 34. Since the nanostructure 34 may be formed only on the catalyst layer 32_2, which may be exposed by the second hole 40h, even if the catalyst layer 32_2 is formed in the second hole 40h, the nanostructure 34 affixed to the catalyst layer 32_2 may be substantially identical to the nanostructure 34 illustrated in FIG. 2A.

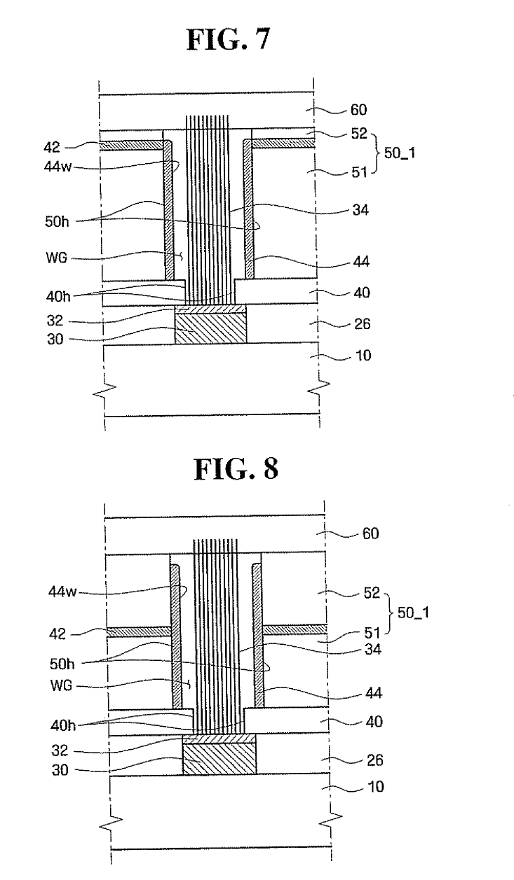

FIGS. 7 and 8 are cross-sectional views illustrating embodiments in which the first insulating film 50 of FIG. 2A may be divided into two or more insulating films and the upper conductive film 42 of FIG. 2A may be interposed between the insulating films. Referring to FIGS. 7 and 8, a first insulating film 50_1 may include a first lower insulating film 51 and a first upper insulating film 52. Some embodiments provide that an upper conductive film 42 may be interposed between the first lower insulating film 51 and the first upper insulating film 52. In some embodiments, the first lower insulating film 51 and the first upper insulating film 52 may be formed of substantially identical materials, such as silicon oxide films, and/or different materials, among others. The boundary, at which the upper conductive film 42 may be disposed, between the first lower insulating film 51 and the first upper insulating film 52, may be formed in an upper portion of a first hole 50h as illustrated in FIG. 7. In some embodiments, the boundary may also be formed in a middle portion of the first hole 50h as illustrated in FIG. 8. In some embodiments, the upper conductive film 42 may be formed on the first insulating film 50_1. Some embodiments provide that the first upper conductive film 52 may be omitted from the structure of FIG. 7, and the structure of FIG. 7 may be modified into a structure in which the upper conductive film 42 directly contacts a second insulating film 60.

In the embodiments of FIGS. 7 and 8, a sidewall of the upper conductive film 42 may be aligned with an inner wall of the first hole 50h and contact the sidewall of a conductive film spacer 44.

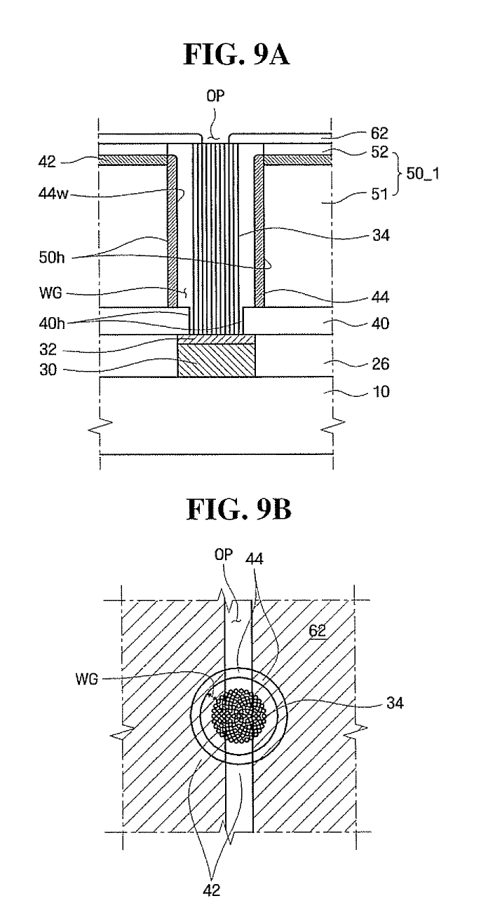

FIGS. 9A and 9B illustrate embodiments in which a second insulating film 62 may be patterned. A structure of FIG. 9A excluding the second insulating film 62 may be substantially identical to the structure of FIG. 7. In some embodiments, the second insulating film 62 may be formed of a line pattern and the line pattern may expose at least a portion OP of a nanostructure 34 and a working gap WG as illustrated in FIG. 9B. Although the second insulating film 62 may not cover part of a central portion of the nanostructure 34, it may cover a peripheral portion of the nanostructure 34, thereby supporting the other end of the nanostructure 34. In this regard, the nanostructure 34 as a whole may be supported. In some embodiments, the second insulating film 62 of FIG. 9A may be formed before a sacrificial spacer is removed. Therefore, unlike the second insulating film 60 illustrated in FIG. 2A, the second insulating film 62 may not need to be formed of a material with poor step coverage. That is, the second insulating film 62 may be formed of a conventional silicon oxide film and/or a conventional silicon nitride film, among others.

Hereinafter, some embodiments of methods of fabricating switch devices will be described. A description of features of the following embodiments that overlap those of embodiments discussed above may be omitted or simplified.

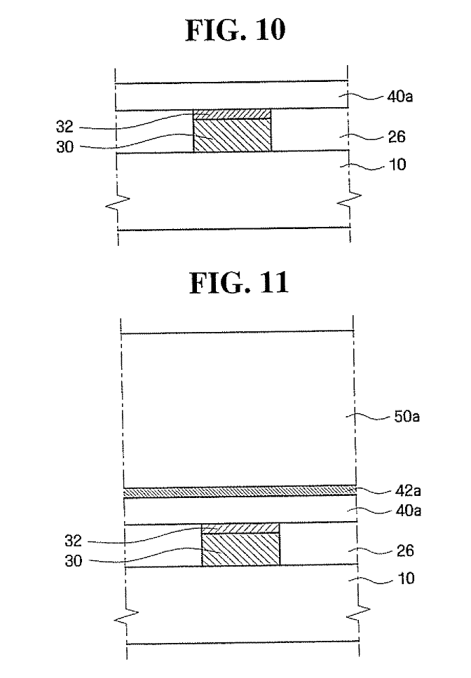

FIGS. 10 through 19 are cross-sectional views sequentially illustrating processing processes included in methods of fabricating a switch device according to some embodiments of the present invention. FIGS. 10 through 19 illustrate processing processes that can be effectively applied to fabricate a switch device according to some embodiments described in FIG. 2A.

Referring to FIG. 10, an insulating film 26 may be formed on a substrate 10. Some embodiments provide that a lower conductive film 30 and a catalyst layer 32 are buried in the insulating film 26. In some embodiments, a Damascene process may be used.

In some embodiments, the catalyst layer 32 may be formed to a thickness of, for example, approximately 1 to 50 nm. Some embodiments provide that the catalyst layer 32 may be formed by using a physical vapor deposition (PVD) method and/or by selectively coating a catalyst solution that contains constituent metal. In some embodiments, the catalyst layer 32 may be deposited by using a magnetron sputtering method and/or an e-beam evaporator and/or by coating transition metal in a power form.

Some embodiments provide that a supporting film 40a is formed on the resultant structure of FIG. 10. In some embodiments, the supporting film 40a may be formed to a thickness of, for example, approximately 10 to 100 nm.

In order to fabricate the switch device illustrated in FIG. 5, the present processing process may be modified. In this regard, some embodiments provide that after the lower conductive film 30 and the catalyst layer 32 are formed on the substrate 10, a film for insulating films (see the insulating film 40_1 of FIG. 5) may be formed on the resultant structure.

Referring, to FIG. 11, an upper conductive film 42a may be formed on the supporting film 40a. In some embodiments, the upper conductive film 42a may be formed to a thickness of, for example, approximately 20 to 100 nm. Some embodiments provide that a first insulating film 50a is formed on the upper conductive film 42a. The first insulating film 50a may be formed to a thickness of, for example, approximately 100 to 500 nm.

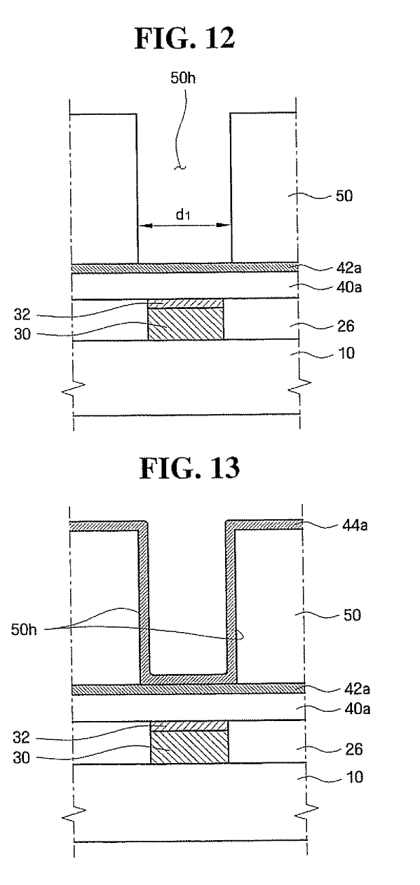

Referring to FIG. 12, the first insulating film 50a is patterned to form a first insulating film 50 that includes a first hole 50h with a first inner diameter d₁. In some embodiments, the first inner diameter d₁ may be less than approximately 100 nm, specifically, approximately 30 to 70 nm. Some embodiments provide that the first hole 50h exposes the upper conductive film 42a and overlaps at least a portion of the lower conductive film 30.

Referring to FIG. 13, a film 44a for conductive film spacers may be formed on a whole surface of the resultant structure of FIG. 12. In some embodiments, the film 44a for conductive film spacers is formed to a thickness of, for example, approximately 5 to 20 nm.

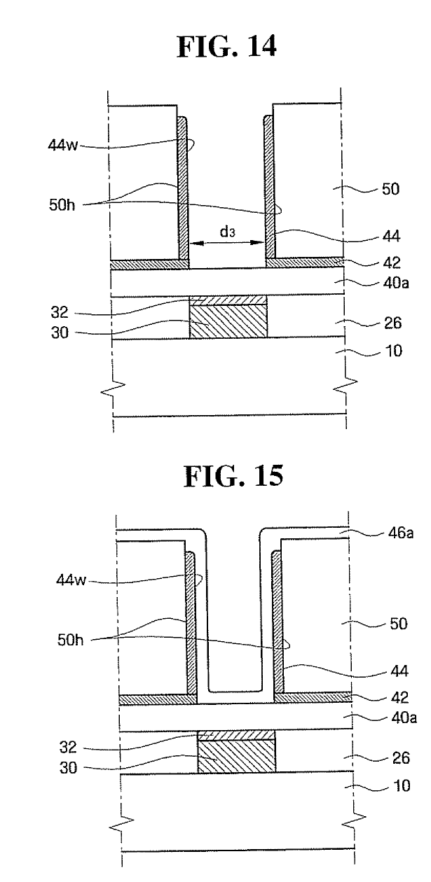

Referring to FIG. 14, the film 44a for conductive film spacers may be etched back to form a conductive film spacer 44. In some embodiments, a thickness of the conductive film spacer 44 may be, for example, approximately 5 to 20 nm. Some embodiments provide that the upper conductive film 42a within the first hole 50h is also removed. In this regard, an upper conductive film 42 having a sidewall aligned with an inner sidewall 44w of the conductive film spacer 44 may be completed. Some embodiments provide that an etching process may be performed in addition to the etch-back process. As a result of the etch-back process and/or the etching process, a third hole, which may be defined by the inner sidewall 44w of the conductive film spacer 44 and may have a third inner diameter d₃, may be formed.

In some embodiments, the upper conductive film 42 may be formed after the first hole 50h is formed and before the film 44a for conductive film spacers is formed. Some embodiments provide that the sidewall of the upper conductive film 42 may be aligned with an inner sidewall of the first hole 50h.

Referring to FIG. 15, a sacrificial spacer 46a may be formed on a whole surface of the resultant structure of FIG. 14. In some embodiments, the sacrificial spacer 46a is formed of an atomic layer deposition (ALD) silicon oxide film to a thickness of, for example, approximately 5 to 20 nm.

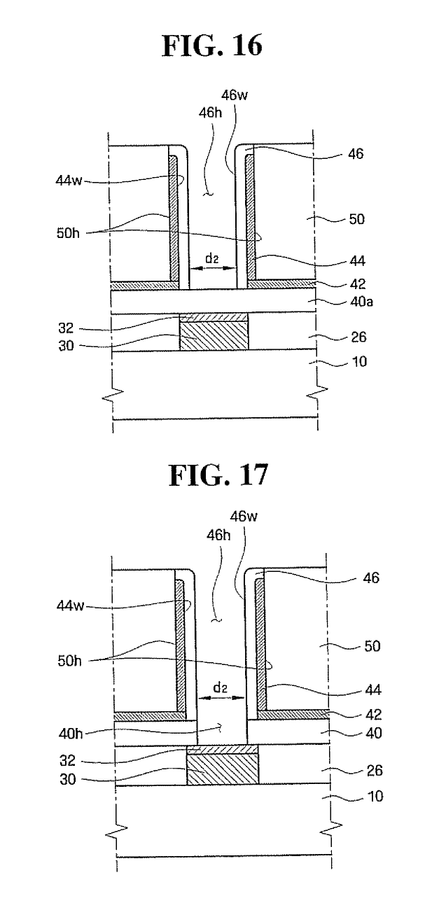

Referring to FIG. 16, the sacrificial spacer 46a may be etched-back to form a sacrificial spacer 46. In some embodiments, a thickness of the sacrificial spacer 46 may be, for example, approximately 5 to 20 nm. Some embodiments provide that the space defined by an inner sidewall 46w of the sacrificial spacer 46 has a second inner diameter d₂. In some embodiments, the sacrificial spacer 46 exposes the supporting film 40a.

Referring to FIG. 17, using the sacrificial spacer 46 as an etch mask, the exposed supporting film 40a may be etched. Some embodiments provide that a supporting film 40 that includes a second hold 40h with the second inner diameter d₂ may be completed. In some embodiments, the catalyst layer 32 is exposed by the second hole 40h. If the sacrificial spacer 46a and the supporting film 40a are formed of substantially identical materials, the processing operations of FIGS. 16 and 17 may be performed simultaneously.

Referring to FIG. 18, a nanostructure 34 may be formed to extend substantially vertically from the exposed catalyst layer 32 and penetrate through the space defined by the second hole 40h and the sacrificial spacer 46. In some embodiments, the nanostructure 34 may be grown on the catalyst layer 32. Some embodiments provide that an end of the nanostructure 34 may be fixed to the catalyst layer 32. Some embodiments provide that the nanostructure 34 may be grown using an electric discharge method, a laser deposition method, a plasma chemical vapor deposition method and/or a thermo-chemical vapor deposition method, among others. In some embodiments, a carbon nanotube may be grown under a temperature of approximately 500 to 900° C., a flow rate of 500 sccm and a pressure of approximately tens through hundreds of tort by injecting a gas containing carbon, such as CH4, C2H2, C2H4, C2H6, CO and/or CO2, and a carrier gas such as H2, Ar and/or N2. In some embodiments, the nanostructure 34 is grown until the other end of the nanostructure 34 is at a level equal to or hi-her than a top surface of the first insulating film 50. In some embodiments, if the nanostructure 34 is grown to a level excessively higher than the top surface of the first insulating film 50, a trimming process, in which a portion of the nanostructure 34 protruding from the top surface of the first insulating film 50 is etched-back, may be performed.

Some embodiments provide that the nanostructure 34 is supported by an inner wall of the second hole 40h that is formed of the supporting film 40 and grows vertically since it is limited by the inner sidewall 46w of the sacrificial spacer 46. In some embodiments, the nanostructure 34 extends substantially vertically within the range in which it overlaps the second hole 40h. Consequently, some embodiments provide that the nanostructure 34 is separated from the conductive film spacer 44 by the sacrificial spacer 46 interposed therebetween.

In order to fabricate the switch device illustrated in FIG. 6, the catalyst layer 32 may be formed after the first hole 50h is formed and before the nanostructure 34 is grown.

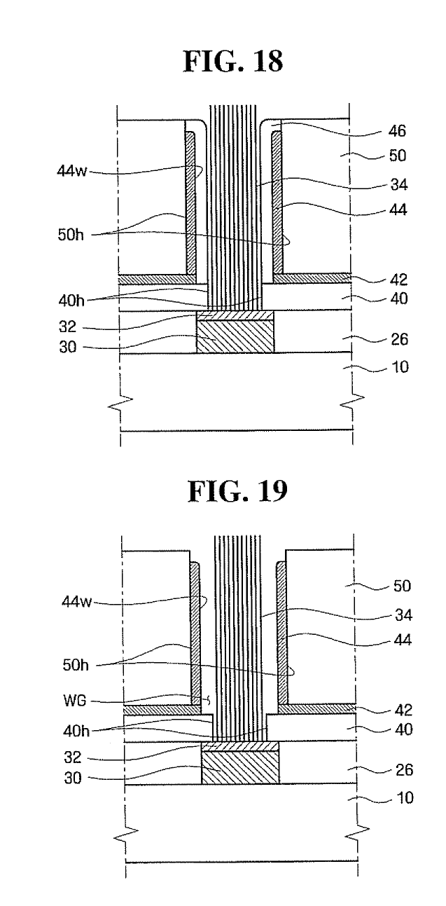

Referring to FIG. 19, the sacrificial spacer 46 may be removed. Some embodiments provide that the sacrificial spacer 46 may be removed in a wet etching process. Some embodiments provide that if the sacrificial spacer 46 is formed of an ALD silicon oxide film and the first insulating film 50 is formed of a silicon nitride film, since they have different etch selectivity, the sacrificial spacer 46 can be selectively removed. Some embodiments provide that if the sacrificial spacer 46 is formed of an ALD silicon oxide film and the first insulating film 50 is formed of a conventional silicon oxide film, since the ALD silicon oxide film and the conventional silicon oxide film have different etch selectivity, the sacrificial spacer 46 can be selectively removed. In some embodiments, an etching etchant applied to the wet etching process may have a 5 to 20 times higher etch rate for the sacrificial space 46 than the first insulating film 50.

In some embodiments, as a result of removing the sacrificial spacer 46, a working gap WG may be formed between the conductive film spacer 44 and the nanostructure 34. In this regard, the working gap WG may be a spacer-shaped air gap.

Referring back to FIG. 2A, a second insulating film 60 may formed on a whole surface of the resultant structure of FIG. 19. In some embodiments, since the working gap WG may be formed between the conductive film spacer 44 and the nanostructure 34, the second insulating film 60 may be formed using a process and/or a material having poor step coverage. For example, some embodiments provide that a deposition process using plasma CVD may be used. Some embodiments provide that the second insulating film 60 may be formed of a CVD silicon oxide film such as a P-TEOS film.

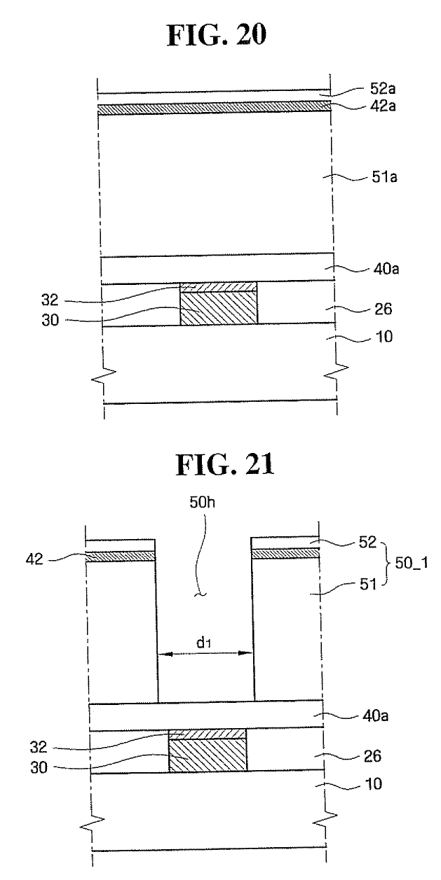

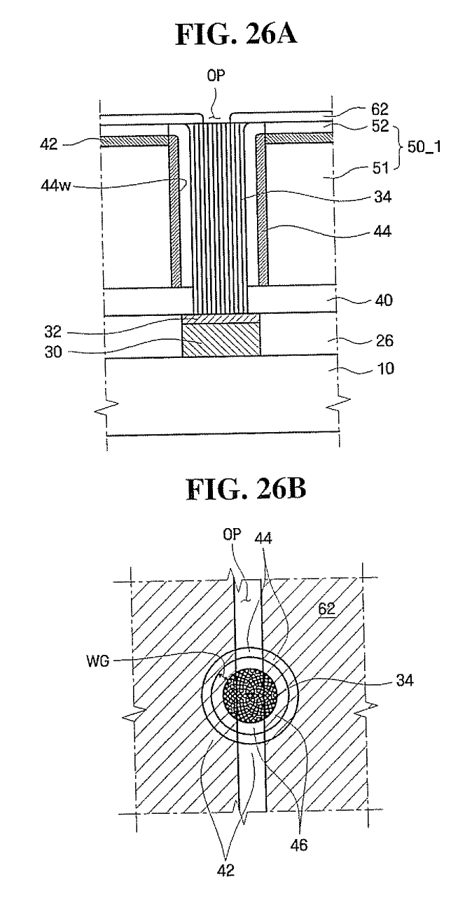

FIGS. 20 through 26A are cross-sectional views sequentially illustrating processing processes included in a method of fabricating a switch device according to some embodiments of the present invention. FIG. 26B is a layout of the switch device illustrated in FIG. 26A. FIGS. 20 through 26B illustrate processing processes which may be applied to embodiments for fabricating switch devices as illustrated in FIGS. 9A and 9B.

Some embodiments provide that processing processes illustrated in FIG. 20 may be substantially identical to the processing process illustrated in FIG. 10 until an insulating film 26 is formed on a substrate 10, a lower conductive film 30 and a catalyst layer 32 are buried in the insulating film 26, and a supporting film 40a is formed. Next, some embodiments provide that a first lower insulating film 51a is formed and a film 42a for upper conductive films is stacked on the first lower insulating film 51a. In some embodiments, a first upper insulating film 52a may then be formed.

Referring to FIG. 21, the first upper insulating film 52a, the film 42a for upper conductive films and the first lower insulating film 51a may be etched. In some embodiments, a first upper insulating film 52, an upper conductive film 42 and a first lower insulating film 51 may be completed, and a first hole 50h with a first inner diameter d₁ may be formed. Some embodiments provide that an inner sidewall of the upper conductive film 42 is aligned with an inner wall of the first hole 50h. Some embodiments provide that the inner sidewalls of the upper conductive film 42 form the first hole 50h.

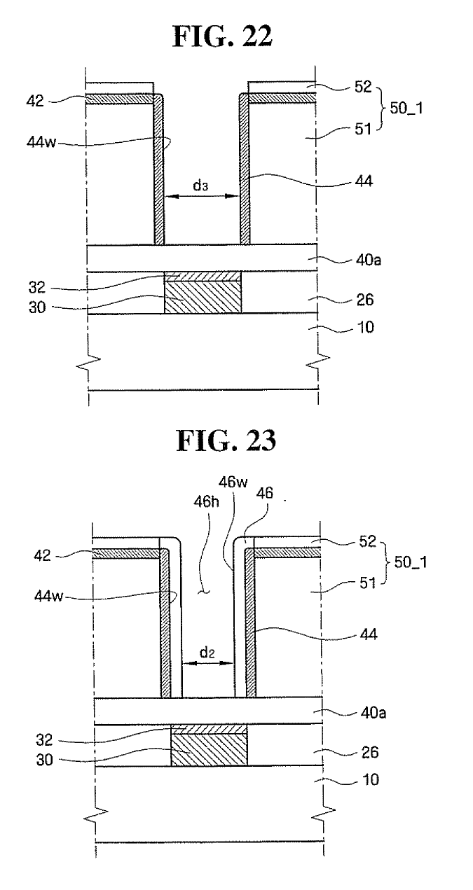

Referring to FIG. 22, a conductive film spacer 44 may be formed using methods that may be substantially identical to methods described above with reference to FIGS. 13 and 14. In some embodiments, since the upper conductive film 42 was already patterned in the previous processing process, the conductive film spacer 44 may not be patterned in the present processing process unlike in the processing processes of FIGS. 13 and 14. Some embodiments provide that after the conductive film spacer 44 is formed, the inner sidewall of the upper conductive film 42 may contact an outer sidewall of the conductive film spacer 44 and a third hole, which is defined by an inner sidewall 44w of the conductive film spacer 44 and has a third inner diameter d₃, may be formed.

Referring to FIG. 23, a sacrificial spacer 46 may be formed using, methods substantially identical to methods described above with reference to FIGS. 15 and 16.

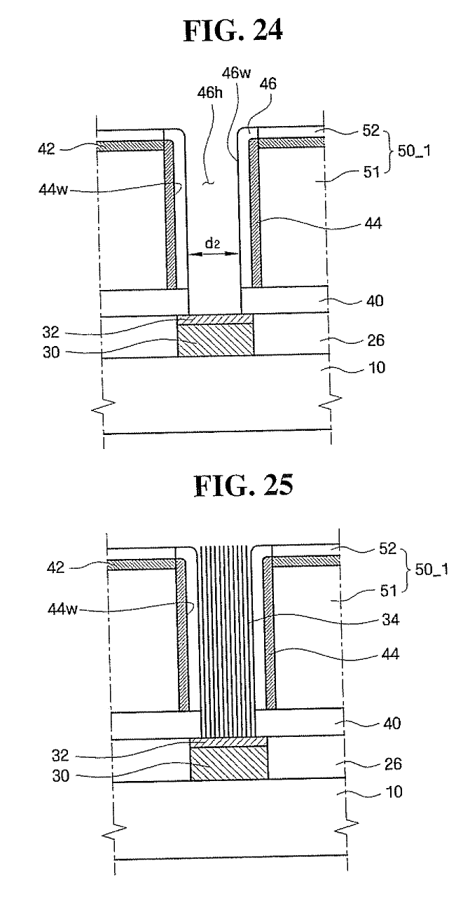

Referring to FIG. 24, a supporting film 40 having a second hole 40h with a second inner diameter d₂ may be formed using methods substantially identical to methods described above with reference to FIG. 17.

Referring to FIG. 25, a nanostructure 34 may be formed on the exposed catalyst layer 32. Some embodiments provide that the present processing process is substantially identical to that of FIG. 18. In some embodiments, if the nanostructure 34 is grown to a level excessively higher than a top surface of a first insulating film 50_1, a trimming process, in which a portion of the nanostructure 34 protruding from the top surface of the first insulating film 50_1 is etched-back, may be performed.

Referring to FIGS. 26A and 26B, a second insulating film 62 may be formed on the resultant structure of FIG. 25. Some embodiments provide that the insulating film 62 may be formed of a line pattern exposing at least a portion OP of the nanostructure 34 and a working gap WG.

In some embodiments, the structure on which the second insulating film 62 is formed may still include the sacrificial spacer 46 in the present processing processes, in contrast with the processing processes of FIGS. 19 and 2A. In this regard, in the present processing processes, it may not be necessary to form the second insulating film 62 using a process and/or a material with poor step coverage. For example, some embodiments provide that a conventional CVD process and/or a low pressure CVD (LPCVD) process as well as a plasma CVD process may be applied. In some embodiments, the second insulating film 62 may be formed of a conventional silicon oxide film.

Some embodiments provide that the sacrificial spacer 46 may be selectively removed to complete the switch device illustrated in FIGS. 9A and 9B. In some embodiments, the sacrificial spacer 46 may be removed using methods substantially identical to methods used in FIG. 19. As described above with reference to FIG. 19, if the sacrificial spacer 46 is formed of an ALD silicon oxide film, it may have different etch selectivity from those of the first lower insulating film 51, the first upper insulating film 52 and/or the second insulating film 62. In some embodiments, the sacrificial spacer 46 may be selectively removed using the different etch selectivity. In particular, since the first lower insulating film 51 may be covered by the conductive film spacer 44 and the upper conductive film 42, an attack by an etching etchant may be prevented.

In order to fabricate embodiments of a switch device as illustrated in FIGS. 7 and 8, the processing processes described above with reference to FIGS. 19 and 2A may be performed before the processing process of FIG. 26A.

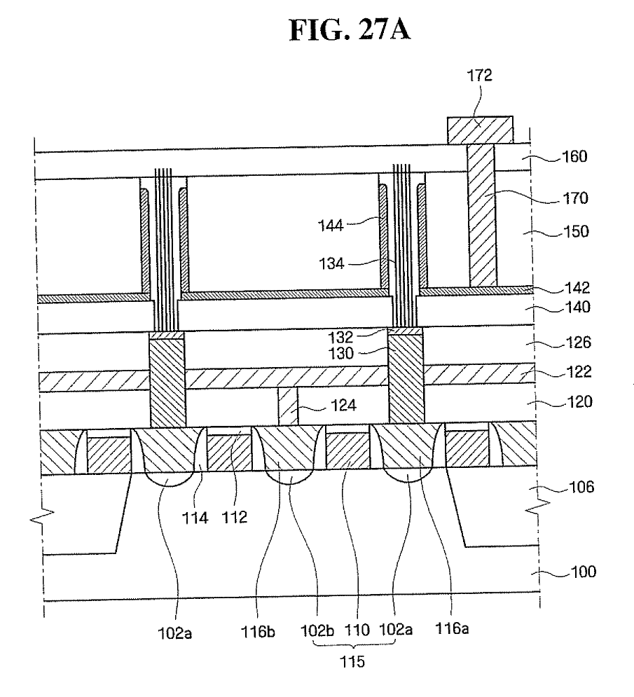

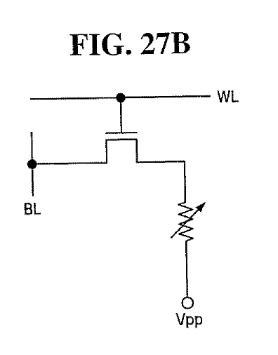

The switch devices and the methods of fabricating the same according to embodiments of the present invention may be applied to semiconductor memory devices. Hereinafter, embodiments of a switch device of FIG. 2A may be applied to a semiconductor memory device, which will be described with reference to FIGS. 27A and 27B. In some embodiments, the switch device of FIG. 2A can be replaced with the switch devices of FIGS. 4 through 9A and applied accordingly to a semiconductor memory device in the following embodiments.

FIG. 27A is a cross-sectional view of a semiconductor memory device according to some embodiments of the present invention. Referring to FIG. 27A, the semiconductor memory device according to some embodiments of a present invention includes a cell transistor 115 formed on a semiconductor substrate 100 and a switch device formed on the cell transistor 115.

More specifically, referring to FIG. 27A, some embodiments provide that a device isolation region 106 defines an active region of the semiconductor substrate 100 and the cell transistor 115 may be formed in the active region. In some embodiments, the cell transistor 115 includes a gate 110, a first source/drain region 102a electrically connected to a storage contact 130 by a first contact plug 116a, and a second source/drain region 102b electrically connected to a bitline contact 124 by a second contact plug 116b. In embodiments illustrated in FIG. 27A, two cell transistors 115 connected respectively to corresponding storage contacts 130 may be commonly connected to one bitline contact 124.

In some embodiments, the gate 110 is formed on the semiconductor substrate 100 and is formed of a conductive film such as a polysilicon film, a metal film and/or a metal silicide film. Some embodiments provide that a gate insulating film (not shown) is interposed between the gate 110 and the semiconductor substrate 100. In some embodiments, a gate spacer 114 is formed on each sidewall of the gate 110. Some embodiments provide that a hard mask 112 may be formed on the gate 110.

In some embodiments, the first and second source/drain regions 102a and 102b may be formed by implanting impurity ions into the semiconductor substrate 100. If the semiconductor substrate 100 is a P-type substrate, impurities implanted into the semiconductor substrate 100 may include N-type impurities.

In some embodiments, the first contact plug 116a is formed on the first source/drain region 102a between the gate spacers 114, and the second contact plug 116b is formed on the second source/drain region 102b. Some embodiments provide that the first contact plug 116a and the second contact plug 116b may be formed in a self-aligned constant (SAC) process. In some embodiments, the first contact plug 116a and the second contact plug 116b may be formed of polysilicon.

Some embodiments provide that an inter-layer insulating film 120 is formed on the cell transistor 115, the first contact plug 116a and the second contact plug 116b, and a bitline 122 is formed on the inter-layer insulating film 120. In some embodiments, an insulating film 126 is formed on the bitline 122.

Some embodiments provide that the bitline contact 124, which electrically connects the bitline 122 to the second contact plug 116b, is formed in the inter-layer insulating film 120. In some embodiments, the storage contact 130 is formed in and penetrates through the inter-layer insulating film 120 and the insulating film 126. Some embodiments provide that the storage contact 130 corresponds to the lower conductive film 30 of FIG. 2A, and the catalyst layer is formed on the storage contact 130. Some embodiments provide that the insulating film 126 corresponds to the insulating film 26 of FIG. 2A.

In some embodiments, a supporting film 140, an upper conductive film 142, a first insulating film 150, a second insulating film 160, a conductive film spacer 144 and a nanostructure 134 are formed on the insulating film 126, and may include structures that are substantially identical to those of the supporting film 40, the upper conductive film 42, the first insulating film 50, the second insulating film 60, the conductive film spacer 44 and the nanostructure 134 described above with reference to FIG. 2A.

In FIG. 27A, a metal wiring 172 may be formed on the second insulating film 160. Some embodiments provide that an upper conductive film contact 170 is formed that penetrates through the second insulating film 160 and the first insulating film 150 and electrically connects the metal wiring 172 to the upper conductive film 142. In some embodiments, a voltage may be applied to the conductive film spacer 144 via the metal wiring 172, the upper conductive film contact 170 and/or the upper conductive film 142, sequentially.

FIG. 27B is a schematic circuit diagram for explaining the operation of the semiconductor memory device of FIG. 27A. The operation of the semiconductor memory device will now be described with reference to FIGS. 27A and 27B.

Initially, the programming operation of the semiconductor memory device will be described. If a gate driving signal is transmitted to the gate 110 from a wordline WL, the cell transistor 115 is turned on. If a data signal is transmitted to a bitline BL and a predetermined voltage Vpp is applied to the metal wiring 172, an electric attraction or repulsive force acts on the nanostructure 134 according to the difference between a voltage applied to the storage contact 130 from the bitline BL and a voltage applied to the conductive film spacer 144 from the metal wiring 172. Accordingly, as described above with reference to FIGS. 2A and 3A, the nanostructure 134 may bend within a working gap WG and thus contact the conductive film spacer 144 or return to its original state, in which it is disposed vertically, and thus be separated from the conductive film spacer 144. Hence, a different data sisal may be stored according to whether the storage contact 130 is electrically connected to the conductive film spacer 144. As described above, since the state in which the nanostructure 134 is bent or the original state to which the nanostructure 134 has returned can be maintained even if power supply thereto is stopped, the semiconductor memory device can be applied as a non-volatile memory device.

Data input to the switch device may be read using a difference in resistance according to whether the nanostructure 134 and the conductive film spacer 144 contact each other or are separated from each other. In this regard, if the gate driving signal is transmitted to the gate 110 from the wordline WL, the cell transistor 115 is turned on. If a predetermined voltage is applied to the metal wiring 172, a different voltage value (or a current value) is detected from the bitline BL according to whether the nanostructure 134 and the conductive film spacer 144 contact each other or are separated from each other. Using the different voltage value (or the current value), stored data can be read from the switch device.

Some embodiments provide that the semiconductor memory device illustrated in FIG. 27A can be fabricated using a combination of the methods of fabricating a switch device according to embodiments described herein and conventional methods of fabricating a semiconductor memory device. That is, some embodiments provide that the cell transistor 115 is formed on the semiconductor substrate 100 using various methods known to the art, and the first contact plug 116a and the second contact plug 116b are formed using the SAC process. Then, after the inter-layer insulating film 120 is formed, a bitline contact hole is formed in the inter-layer insulating film 120. The bitline contact hole may be buried to form the bitline contact 124. In some embodiments, the bitline 122 is formed on the inter-layer insulating film 120. Then, some embodiments provide that the insulating film 126 is formed, and a storage contact hole, which penetrates through the inter-layer insulating film 120 and the insulating film 126, is formed. Thereafter, the storage contact 130 burying the storage contact hole may be formed. The subsequent processes may be substantially identical to methods of fabricating a switch device described herein. After the switch device is completed, an upper conductive film contact hole, which penetrates through the second insulating film 160 and the first insulating film 150, may be formed and then buried. As a result, the upper conductive film contact 170 may be formed. Then, the metal wiring 172 connected to the upper conductive film contact 170 may be formed.

In a switch device according to some embodiments of the present invention, when the switch device is turned off, a reliable non-contact may be maintained between a nanostructure and a conductive film spacer with a working gap interposed therebetween. When the switch device is turned on, the nanostructure and the conductive film spacer can contact each other regardless of a position at which the nanostructure bends. Some embodiments provide that since an area where the conductive film spacer contacts the nanostructure may be increased, contact resistance may be reduced. In this regard, the switch device can be reliably tuned on or off even if a relatively low voltage is applied thereto.

Although the present invention has been described in terms of specific embodiments, the present invention is not intended to be limited by the embodiments described herein. Thus, the scope may be determined by the following claims.

1. A switch device, comprising:
a lower conductive film formed on a substrate;
a first insulating, film formed on the lower conductive film and including a first hole which exposes at least a portion of the lower conductive film;
a conductive film spacer formed on an inner wall of the first hole of the first insulating film; and
a nanostructure having an end electrically connected to the lower conductive film, the nanostructure comprising a nanotube and/or a nanowire, extending substantially vertically from the lower conductive film and penetrating through the first hole, and separated from the conductive film spacer with a working gap interposed therebetween.

2. The switch device of claim 1, further comprising a supporting film disposed under the first insulating film and having a second hole that exposes the at least a portion of the lower conductive film together with the first hole, wherein the nanostructure penetrates through the second hole and the first hole and extends substantially vertically.

3. The switch device of claim 2, further comprising an upper conductive film that is configured to contact the conductive film spacer and to include a sidewall aligned with the inner wall of the first hole or an inner sidewall of the conductive film spacer.

4. The switch device of claim 3, wherein the upper conductive film is formed on the first insulating film and/or between the first insulating film and the supporting film.

5. The switch device of claim 3, wherein the first insulating film comprises a first lower insulating film and a first upper insulating film that are sequentially stacked and wherein the upper conductive film is formed between the first lower insulating film and the first upper insulating film.

6. The switch device of claim 2, wherein an inner diameter of space defined by the inner sidewall of the conductive film spacer is greater than an inner diameter of the second hole and wherein the supporting film protrudes from the inner sidewall of the conductive film spacer.

7. The switch device of claim 2, wherein the working gap comprises a spacer-shaped air gap.

8. The switch device of claim 2, further comprising a catalyst layer formed on the lower conductive film, wherein one end of the nanostructure is fixed to the catalyst layer and electrically connected to the lower conductive film by the catalyst layer.

9. The switch device of claim 2, further comprising a second insulating film formed on the first insulating film, wherein the second insulating film is configured to cover the first hole and/or support the other end of the nanostructure.

10. The switch device of claim 9, wherein the second insulating film comprises a plasma chemical vapor deposition (CVD) silicon oxide film.

11. The switch device of claim 2, further comprising a second insulating film formed on the first insulating film, wherein the second insulating film comprises a line pattern that is configured to expose at least a portion of the nanostructure and at least a portion of the working gap.

12. A switch device comprising:
a first conductive film;
a nanostructure comprising a nanotube and/or a nanowire on the first conductive film, the nanostructure configured to extend substantially perpendicular to a surface of the first conductive film; and
a second conductive film configured to extend substantially parallel to the nanostructure and substantially perpendicular to the surface of the first conductive film, the second conductive film separated from the nanostructure and defining a working gap interposed therebetween.

13. The switch device of claim 12, wherein the nanostructure is configured to electrically connect or disconnect the first conductive film and the second conductive film responsive to an electro-dynamic force acting on the nanostructure.

14. A method of fabricating a switch device, the method comprising:
forming a lower conductive film on a substrate;
forming a first insulating film on the lower conductive film;
patterning the first insulating film to form a first hole in the first insulating film;
forming a conductive film spacer on an inner wall of the first hole;
forming a sacrificial spacer on a sidewall of the conductive film spacer;
forming a nanostructure including one end electrically connected to the lower conductive film, the nanostructure comprising a nanotube and/or a nanowire, the nanostructure extending substantially vertically from the lower conductive film and penetrating through the first hole; and
removing the sacrificial spacer to define a working gap interposed between the nanostructure and the conductive film spacer.

15. The method of claim 14, further comprising:
forming a supporting film on the lower conductive film before forming the first insulating film; and
forming a second hole, which exposes the lower conductive film, in the supporting film by etching the supporting film using the sacrificial spacer as an etch mask after forming the sacrificial spacer,
wherein the nanostructure is formed to penetrate through the second hole and the first hole and extend substantially vertically.

16. The method of claim 15, further comprising:
forming a film for at least one upper conductive film before forming the first insulating film; and
forming an upper conductive film that includes a sidewall aligned with an inner sidewall of the sacrificial spacer by patterning the film for the at least one upper conductive film after forming the sacrificial spacer.

17. The method of claim 15, further comprising:
forming a film for at least one upper conductive film after forming the first insulating film; and
forming an upper conductive film that includes a sidewall aligned with the inner wall of the first hole by patterning the film for the at least one upper conductive film after forming the first hole.

18. The method of claim 15,
wherein forming the first insulating film comprises forming a first lower insulating film and forming a first upper insulating film,
wherein forming the first insulating film comprises:
forming the first lower insulating film on the supporting film;
forming a film for at least one upper conductive film on the first lower insulating film; and
forming the first upper insulating film on the film for at least one upper conductive film,
wherein patterning the first insulating film comprises patterning the first upper insulating film, the film for at least one upper conductive film and the first lower insulating film,
wherein patterning the upper conductive films comprises forming an upper conductive film that has a sidewall aligned with the inner wall of the first hole.

19. The method of claim 15, further comprising forming a catalyst layer on the lower conductive film, wherein forming the nanostructure comprises vertically growing the nanostructure on the catalyst layer.

20. The method of claim 15, wherein removing the sacrificial spacer comprises performing a wet-etching process.

21-29. (canceled)
